(19) United States
(12) Patent Application Publication
(10) Pub. No.: US 2021/0044050 A1
(43) Pub. Date: Feb. 11, 2021

(54) Solderless Connector

(71) Applicant: GATES CORPORATION, Denver, CO (US)

(72) Inventors: Vigel Russalian, Macomb, MI (US); George Spehar, Clarkson, MI (US); Stephen Reaburn, LaSalle (CA); Victor Church, Rochester Hills, MI (US); Michael Cox, Tecumseh (CA)

(21) Appl. No.: 16/534,146

(22) Filed: Aug. 7, 2019

(51) Int. Cl. H01R 13/508; H02K 3/50; H01R 12/57; H01R 13/426

(52) U.S. Cl. CPC H01R 13/508; H02K 3/50; H05K 2201/1059; H01R 13/426; H01R 12/57

(57) ABSTRACT

A connector comprising a frame having a circular shape and a first surface, a plurality of clips attached to the first surface, each clip comprising having a first tang and a second tang, the first tang and second tang biased toward each other, the first tang and the second tang describing a receiving cavity therebetween, and the receiving cavity for receiving a conductor.

### FIELD OF THE INVENTION

The invention relates to a solderless connector.

### BACKGROUND OF THE INVENTION

The present invention relates to a solderless electrical connector used to connect a circuit board to electrical equipment. The circuit board can be used to control operation of an electric motor.

Representative of the art is U.S. Pat. No. 4,673,232 which discloses a terminal system, wherein, by employing a piece of metallic spring material, the portion which exclusively takes charge of mechanical connection and the portion which exclusively takes charge of electric contact are independently formed on the piece, in other words, the portion taking charge of mechanical connection does not consider the electric contact and the portion taking charge of electric contact does not consider the mechanical connection, therefore, since each portion can fully exert each function, the superiority in mechanical connection and electric contact is obtained.

What is needed is a solderless connector. The present invention meets this need.

### SUMMARY OF THE INVENTION

The primary aspect of the invention is to provide a solderless connector for use in electric motors.

Other aspects of the invention will be pointed out or made obvious by the following description of the invention and the accompanying drawings.

The invention is a connector comprising a frame having a circular shape and a first surface, a plurality of clips attached to the first surface, each clip comprising having a first tang and a second tang, the first tang and second tang biased toward each other, the first tang and the second tang describing a receiving cavity therebetween, and the receiving cavity for receiving a conductor.

The foregoing has outlined rather broadly the features and technical advantages of the present invention in order that the detailed description of the invention that follows may be better understood. Additional features and advantages of the invention will be described hereinafter which form the subject of the claims of the invention. It should be appreciated by those skilled in the art that the conception and specific embodiment disclosed may be readily utilized as a basis for modifying or designing other structures for carrying out the same purposes of the present invention. It should also be realized by those skilled in the art that such equivalent constructions do not depart from the spirit and scope of the invention as set forth in the appended claims. The novel features which are believed to be characteristic of the invention, both as to its organization and method of operation, together with further objects and advantages will be better understood from the following description when considered in connection with the accompanying figures. It is to be expressly understood, however, that each of the figures is provided for the purpose of illustration and description only and is not intended as a definition of the limits of the present invention.

### BRIEF DESCRIPTION OF THE DRAWINGS

The accompanying drawings, which are incorporated in and form a part of the specification, illustrate preferred embodiments of the present invention, and together with a description, serve to explain the principles of the invention.

FIG. 1 is a cross section view of the motor.

FIG. 2 is a detail of the inventive connector.

FIG. 3 is a detail of the inventive connector.

FIG. 4 is a detail of the inventive connector.

FIG. 5 is a perspective detail of the inventive connector.

FIG. 6 is an exploded view.

### DETAILED DESCRIPTION OF THE PREFERRED EMBODIMENT

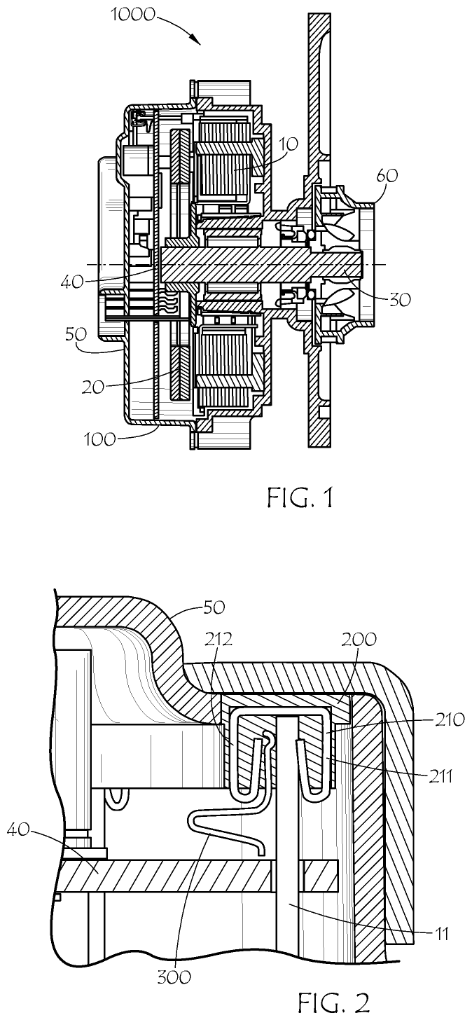

FIG. 1 is a cross section view of the motor. The inventive solderless connector is a part of an axial flux motor assembly. The axial flux motor comprises a stator 10, rotor 20, shaft 30, mother board 40, housing 50, impeller 60. Stator 10 comprises a plurality of phase coil packs, typically three coils for each phase.

The motor is used to circulate cooling fluid for an engine. However, the motor may be used for any suitable application as may be required by a user.

While the connector is described in context with an axial flux motor, the connector may be used in any circumstance where a solderless connector may be used, for example, in a DC motor, AC motor, mother board connection to any external source, or for any connection between two components requiring an electrical connection.

FIG. 2 is a detail of the inventive connector. The connector is shown within the axial flux motor. The connector comprises frame 200. Frame 200 may comprise plastic or other suitably rigid material. Attached to frame 200 is a plurality of clips 210. Each clip 210 is mounted to frame 200 about a circumference. Clips 210 are equally spaced from each other, but may also be arranged as required to accommodate any internal wiring scheme. Frame 200 is mounted to housing component 50. Frame 200 is not required to practice the invention and clips 210 may be mounted to a mounting surface individually as required by a given application.

Projecting from mother board 40 is a lead 300. Lead 300 engages clip 210. Stator wire 11 extends from each stator coil pack. Each wire 11 engages and is gripped by clip 210, thereby putting lead 300 and wire 11 into electrical contact. Wire 11 and lead 300 each project into clip 210. Clip 210 and lead 300 are each metallic and therefore conductive. In an alternate embodiment clips 210 are not conductive and may be made of plastic or resin for example.

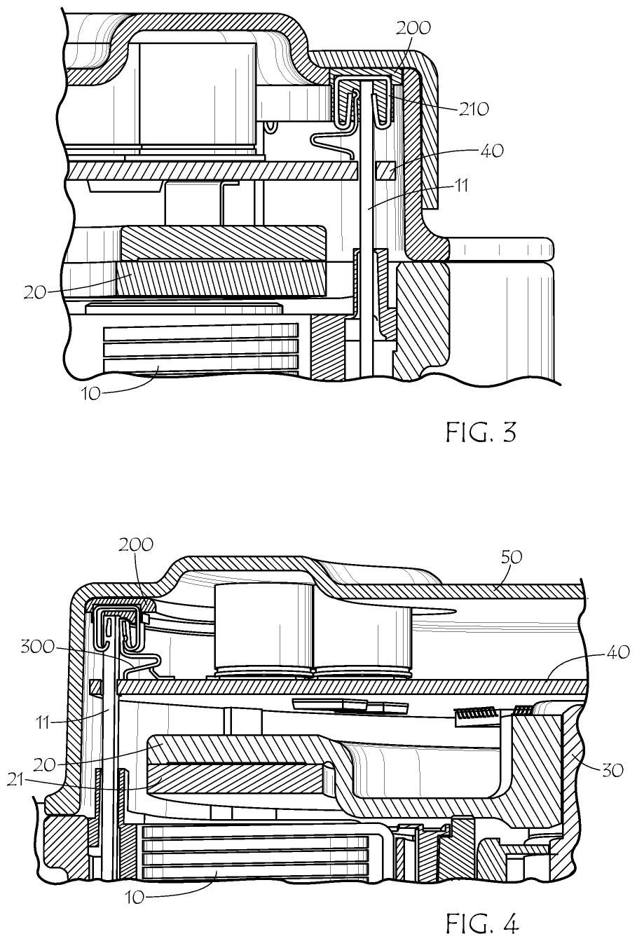

FIG. 3 is a detail of the inventive connector. Mother board 40 comprises the electronics to control and operate the motor. The circuits and associated software are known in the art.

FIG. 4 is a detail of the inventive connector. Rotor 20 comprises a plurality of permanent magnets 21. With the exception of the solderless connector assembly the axial flux motor is generally known in the art.

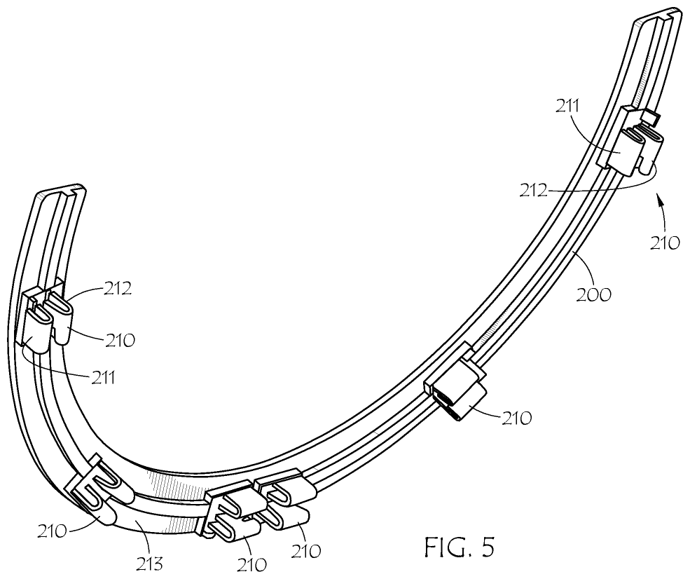

FIG. 5 is a perspective detail of the inventive connector. Frame 200 is circular in form. Clips 210 are evenly spaced about the frame. Frame 200 may describe a full circle (360°), or a portion of a circle, for example, 90° or 180°, or some other suitable portion of a circle that is less than 360°. Frame 200 may also comprise individual spaced segments disposed about a mounting surface. The number of clips 210 may be one, two or a plurality depending upon the application.

Each clip 210 comprises a first “U” shaped tang 211 and second “U” shaped tang 212. Tang 211 and tang 212 face each other so as to resiliently grip lead 300 and wire 11 therebetween in receiving cavity 213. Tang 211 and tang 212 are biased toward each other. Clip 210 electrically connects mother board lead 300 to stator wire 11 in a single connector.

The connection between wire 11 and lead 300 is easily made during assembly of the motor. Mother board 40 is installed in the housing. Wire 11 projects through mother board 40. Lead 300 extends from mother board 40 and is adjacent to wire 11. Frame 200 is mounted to housing 50. As housing 50 is pressed to the motor, wire 11 and lead 300 simultaneously slip into and engage clip 210. Each wire 11 and lead 300 are mechanically retained between tangs 211 and 212, thereby making electrical contact between them. The mechanical connection thus eliminates the need for soldering or other means of connecting the lead and wire. Connector 200 connects mother board 40 to coils 10. Mother board 40 and the circuitry thereon control operation of the motor.

The inventive solderless connector provides quick and easy electrical connection between the motor electronics and stator. It eliminates the need for making a connection using some form of solder or brazing. It also allows the connection to be made in a very short period of time, thereby reducing manufacturing costs.

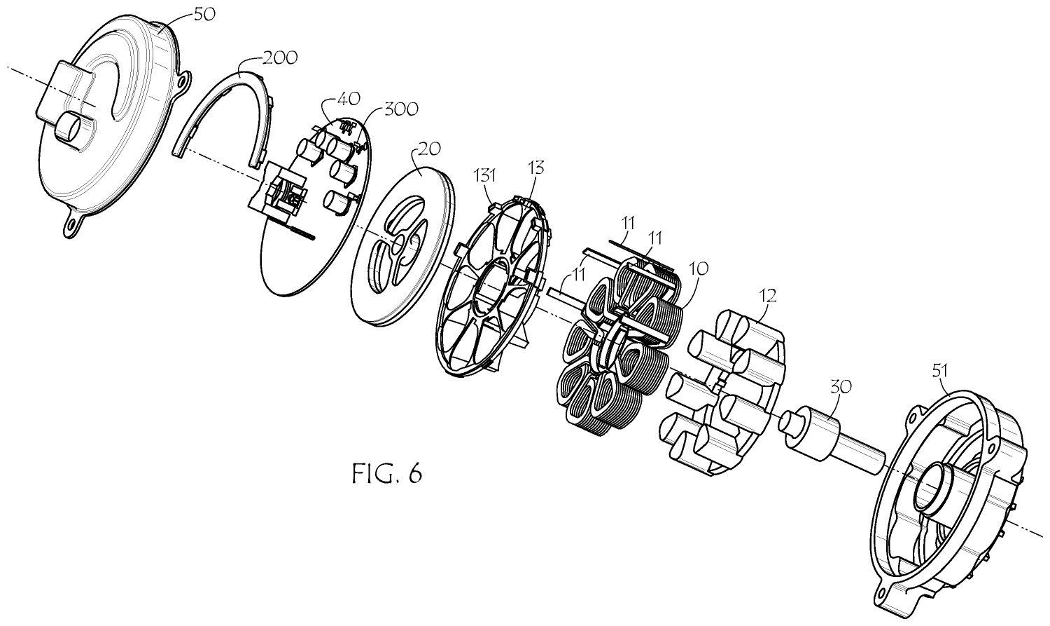

FIG. 6 is an exploded view. Coils 10 are wound about frame 12. Segments of insulator 13 are disposed between coils 10. Each wire 11 extends through a respective insulator guide 131. Housing component 51 connects to housing 50.

Although a form of the invention has been described herein, it will be obvious to those skilled in the art that variations may be made in the construction and relation of parts without departing from the spirit and scope of the invention described herein. Unless otherwise specifically noted, components depicted in the drawings are not drawn to scale. Further, it is not intended that any of the appended claims or claim elements invoke 35 U.S.C. § 112(f) unless the words “means for” or “step for” are explicitly used in the particular claim. The present disclosure should in no way be limited to the exemplary embodiment or numerical dimensions if any illustrated in the drawings and described herein.

We claim:

1. A connector comprising:
a frame having a circular shape and a first surface;
a plurality of clips attached to the first surface;
each clip comprising having a first tang and a second tang, the first tang and second tang biased toward each other;
the first tang and the second tang describing a receiving cavity therebetween; and
the receiving cavity for receiving a conductor.

2. The connector as in claim 1, wherein the clips are conductive.

3. The connector as in claim 1, wherein the plurality of clips are spaced from each other about the circumference of the frame.

4. The connector as in claim 1, wherein the clips are not conductive.

5. The connector as in claim 1, wherein the clips are metallic.

6. The connector as in claim 1, wherein the clips are plastic.

7. A connector comprising:
a frame having a circular shape and a first surface;
a plurality of clips attached to the first surface, each clip is not conductive;
each clip comprising having a first tang and a second tang, the first tang and second tang biased toward each other;
the first tang and the second tang describing a receiving cavity therebetween; and
the receiving cavity for receiving a first conductor and second conductor.

8. A connector comprising:
a frame;
a clip attached to the frame;
the clip comprising a first tang and a second tang, the first tang and second tang biased toward each other;
the first tang and the second tang describing a receiving cavity therebetween; and
the receiving cavity for receiving a conductor.

9. The connector as in claim 8, wherein the clip is conductive.

10. The connector as in claim 8 further comprising a plurality of clips attached to the frame, and the frame is circular.

11. The connector as in claim 8, wherein the clip is not conductive.

12. The connector as in claim 8, wherein the clip is metallic.

13. The connector as in claim 8, wherein the clip is plastic.
